(19) United States
(12) Patent Application Publication
(10) Pub. No.: US 2009/0091345 A1
(43) Pub. Date: Apr. 9, 2009

(54) STRUCTURE FOR PROVIDING A DUPLICATE TEST SIGNAL OF AN OUTPUT SIGNAL UNDER TEST IN AN INTEGRATED CIRCUIT

(76) Inventors: Moises Cases, Austin, TX (US); Bhyrav M. Mutnury, Austin, TX (US); Nam H. Pham, Round Rock, TX (US)

Correspondence Address: IBM CORPORATION, INTELLECTUAL PROPERTY LAW;DEPT 917, BLDG. 006-1, 3605 HIGHWAY 52 NORTH, ROCHESTER, MN, 55901-7829, US

(21) Appl. No.: 12/113,386

(22) Filed: May 1, 2008

Related U.S. Application Data
(63) Continuation-in-part of application No. 11/868,071, filed on Oct. 5, 2007.

(51) Int. Cl. G01R 31/02

(52) U.S. Cl. 324/763

(57) ABSTRACT

A design structure embodied in a machine readable storage medium for designing, manufacturing, and/or testing a design is provided. The design structure provides a duplicate test signal of an output signal under test in an integrated circuit including selecting through a multiplexer an output signal under test, the output signal under test selected from a plurality of output signals of the integrated circuit; providing through the multiplexer a duplicate signal of the selected output signal under test; adding a high impedance load on the duplicate signal thereby reducing the amplitude of the duplicate signal; and amplifying the reduced duplicate signal thereby creating the duplicate test signal.

### CROSS-REFERENCE TO RELATED APPLICATION

This application is a continuation-in-part of co-pending U.S. patent application Ser. No. 11/868,071, filed Oct. 5, 2007, which is herein incorporated by reference.

### BACKGROUND OF THE INVENTION

1. Field of the Invention

The field of the invention is generally related to design structures, and more specifically, design structures for providing a duplicate test signal of an output signal under test in an integrated circuit.

2. Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

Computer systems typically contain many integrated circuits. From time to time the output signals of integrated circuits are tested. Such testing typically introduces parasitic effects into the signal that is being tested. Such parasitic effects may include, for example, a severe current drain on the signal or a signal reflection that effectively eliminates the signal in operation. In other cases, the signal being tested is not accurately represented, due to a faulty pin package, when the testing of that signal occurs at the pin of a faulty pin package.

### SUMMARY OF THE INVENTION

Methods, integrated circuits, and apparatus for providing a duplicate test signal of an output signal under test in an integrated circuit are disclosed. The methods include selecting through a multiplexer an output signal under test, the output signal under test selected from a plurality of output signals of the integrated circuit; providing through the multiplexer a duplicate signal of the selected output signal under test; adding a high impedance load on the duplicate signal thereby reducing the amplitude of the duplicate signal; and amplifying the reduced duplicate signal thereby creating the duplicate test signal.

The integrated circuits include a plurality of output signal lines; a multiplexer, the multiplexer having as inputs the output signal lines; a high impedance load, the high impedance load connected to an output of the multiplexer; and an amplifier; the amplifier connecting the high impedance load to an output test line.

The apparatus includes an integrated circuit, the integrated circuit comprising a plurality of output signal lines; a multiplexer, the multiplexer having as inputs the output signal lines; a high impedance load, the high impedance load connected to an output of the multiplexer; and an amplifier, the amplifier connecting the high impedance load to an output test line.

In one embodiment, a design structure embodied in a machine readable storage medium for at least one of designing, manufacturing, and testing a design is provided. The design structure generally includes an integrated circuit for providing a duplicate test signal of an output signal under test. The integrated circuit generally includes a plurality of output signal lines, a multiplexer, the multiplexer having as inputs the output signal lines, a high impedance load, the high impedance load connected to an output of the multiplexer, and an amplifier, wherein the amplifier connects the high impedance load to an output test line.

In another embodiment, a design structure embodied in a machine readable storage medium for at least one of designing, manufacturing, and testing a design is also provided. The design structure generally includes an apparatus for providing a duplicate test signal of an output signal under test. The apparatus generally includes an integrated circuit, the integrated circuit comprising a plurality of output signal lines, a multiplexer, the multiplexer having as inputs the output signal lines, a high impedance load, the high impedance load connected to an output of the multiplexer, and an amplifier, wherein the amplifier connects the high impedance load to an output test line.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a line drawing of a system for providing a duplicate test signal of an output signal under test in an integrated circuit according to embodiments of the present invention.

FIG. 2 sets forth a flow chart illustrating an exemplary method for providing a duplicate test signal of an output signal under test in an integrated circuit according to embodiments of the present invention.

FIG. 3 sets forth a flow chart illustrating a further exemplary method for providing a duplicate test signal of an output signal under test in an integrated circuit according to embodiments of the present invention.

FIG. 4 is a flow diagram of a design process used in semiconductor design, manufacture, and /or test.

### DETAILED DESCRIPTION OF EXEMPLARY EMBODIMENTS

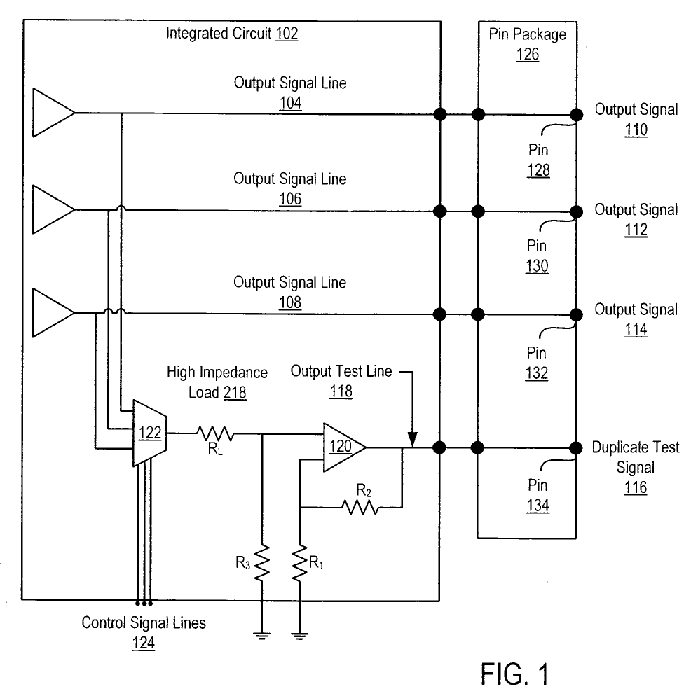

Exemplary methods, integrated circuits, and apparatus for providing a duplicate test signal of an output signal under test in accordance with the present invention are described with reference to the accompanying drawings, beginning with FIG. 1. FIG. 1 sets forth a line drawing of a system for providing a duplicate test signal of an output signal under test in an integrated circuit (102) according to embodiments of the present invention. The system of FIG. 1 is generally capable of providing a duplicate test signal (116) of an output signal under test in an integrated circuit (102) according to embodiments of the present invention. The system of FIG. 1 is capable of selecting through a multiplexer (122) an output signal under test, the output signal under test selected from a plurality of output signals (110, 112, 114) of the integrated circuit (102); providing through the multiplexer (122) a duplicate signal of the selected output signal under test; adding a high impedance load (218) on the duplicate signal thereby reducing the amplitude of the duplicate signal; and amplifying the reduced duplicate signal thereby creating the duplicate test signal (116). The impedance of the high impedance load (218) is established such that parasitic effects, including current drain and signal reflection, on the output signal under test are reduced while maintaining the signal for testing purposes.

The system of FIG. 1 includes an integrated circuit (102). An integrated circuit is a miniaturized electronic circuit, typically including semiconductor devices as well as passive components, that is manufactured in the surface of a thin substrate of semiconductor material. Integrated circuits typically include several input and output signal lines, traces on the semiconductor material, for receiving and providing electrical signals. These signal lines are typically connected to a printed circuit board or other electrical connection for use in a larger electrical system through a pin package. In the system of FIG. 1, the integrated circuit includes three output signal lines (104, 106, 108) that carry output signals (110, 112, 114).

A pin package connects the output and input lines of an integrated circuit to a set of pins, one pin corresponding to each of the output and input signal lines of the integrated circuit. In the system of FIG. 1, for example, the three output signal lines (104, 106, 108) of the integrated circuit (102) are connected through a pin package (126) to pins (128, 130, 132). Each pin (128, 130, 132) may be connected to a printed circuit board or other electrical connection.

Connections between the signal lines of the integrated circuit and the pin package may be implemented in various ways. One such implementation of the connection between the signal lines of the integrated circuit and the pin package is by wire bond. Wire bonding is typically carried out by connecting a wire between a contact pad at the end of a trace of the integrated circuit and a contact pad on the pin package. The wires in a wire bonded chip are typically gold, aluminum, or copper with diameters ranging from 15 micrometers to several hundred micrometers. The wire is typically attached at both ends using some combination of heat, pressure, and ultrasonic energy to make a weld.

As an alternative to wire bonding, the integrated circuit and pin package may be implemented in a flip chip. A flip chip is a type of mounting used for semiconductor devices which does not require any wire bonds. Instead, the final wafer processing step during the manufacture of the chip deposits solder bumps on pads of the output signal lines. The solder bumps are used to connect directly to the pin package. The pads of the output signal lines are typically on the top of the integrated circuit, such that to directly connect the solder bumps on the pad directly to the pin package, the integrated circuit is “flipped” face down.

The system of FIG. 1 also includes a multiplexer (122) having as inputs the output signal lines (104, 106, 108) of the integrated circuit (102). A multiplexer is a device that selects one of many inputs to output in a single channel. An input to a multiplexer may be selected as the multiplexer's output by using control signal lines. Each input of the multiplexer is associated with a unique combination of logic high and logic low signals on the control signal lines. In the system of FIG. 1, the multiplexer may select any of the three output signal lines (104, 106, 108) as its output in dependence upon the control signal lines (124). The control signal lines (124) may be connected to any electrical connection capable of transmitting a logic high and logic low. Each control signal line (124) may also be connected through the pin package (126) to a pin for connection to the same printed circuit board that the output signal lines are connected.

The system of FIG. 1 also includes a high impedance load (218) that is connected to an output of the multiplexer (122). Although the system of FIG. 1 shows a resistor (R_{L}) as the high impedance load (218), readers of skill in the art will recognize that typical operational amplifiers, such as amplifier (120), include a high impedance load. That is, the high impedance load (218) and the amplifier (120) may be a single component. The resistor (R_{L}) of FIG. 1 is shown as the high impedance load, for clarity. Readers of skill in the art will recognize that other electrical components may be used to implement such a high impedance load and each such electrical component is well within the scope of the present invention.

A high impedance load, such as the resistor (R_{L}) in FIG. 1, reduces the amplitude of a signal on the output of the multiplexer. The higher the impedance of the high impedance load, the lower the amount of current that is drawn from the output signal line selected as the output of the multiplexer. The high impedance load also reduces the effects of signal reflection, effectively acting as an open circuit. Signal reflection is the reflection of a signal back to the source of the signal. If no high impedance load is present in the system of FIG. 1, for example, and if signal reflection occurs, the output signal of the multiplexer would be reflected back through the multiplexer to the source of the output signal. If the reflected signal is a duplicate of the source output signal, the reflected output signal and the source output signal may cancel each other, causing little or no signal on the output signal line connected through the pin package. Not only does the high impedance load reduce the effects of signal reflection, but the high impedance load also reduces any transmission line resonance that may be caused without the presence of the high impedance load.

The system of FIG. 1 also includes an amplifier (120) that connects the high impedance load (218) to an output test line (118). An amplifier is a device that is capable of increasing the power of a signal. The amplifier (120) of FIG. 1, for example, increases the amplitude of the reduced output signal and transmits the amplified signal through an output test line (118). The amount a signal is amplified is called gain. The gain in FIG. 1 is determined by the value of the resistors connected to the input and outputs of the multiplexer (120). The following formula defines the gain of the amplifier in the system of FIG. 1:

Gain=((R₁+R₂)/R₁)*(R₃/(R_{L}+R₃))

The amplifier and resistors of FIG. 1 are shown for clarity as an exemplary circuit for amplifying a reduced output test signal of an integrated circuit according to embodiments of the present invention. Readers of skill in the art will recognize, however, that other electrical components may also be used to amplify a reduced output test signal, such as for example, bipolar-junction transistors (‘BJT’), junction gate field-effect transistors (‘JFET’), metal-oxide-semiconductor field-effect transistors (‘MOSFET’), and so on. Each such implementation of the amplification of a reduced output test signal is well within the scope of the present invention.

When the reduced output test signal is amplified, a duplicate test signal is created. The duplicate test signal (116) is “duplicate” in the sense that is identical, or nearly identical, to the signal on the output signal line selected as an input to the multiplexer (122). A duplicate test signal may only be nearly identical due to many factors, such as for example, imperfections in the amplifier circuitry, loss of signal over distances, and other factors as will occur to those of skill in the art.

The system of FIG. 1 also includes an output test line (118) connected through pin package (126) to a pin (134). An output test line is an electrical connection that transmits a duplicate test signal (118) for testing. The output test line may be probed by any electrical testing equipment such as for example, a voltmeter, ammeter, oscilloscope or other testing equipment as will occur to those of skill in the art.

In the system of FIG. 1, the multiplexer (122), high impedance load (218) and amplifier (120) are implemented as part of the integrated circuit (102) and the output test line (118) is connected through the pin package (126). In some cases, testing an output signal line at a pin of the pin package may not provide accurate test results for many reasons, including for example, a failure in the pin package, the inherent electrical characteristics of the pin package, reflections due to the channel at the pin package, or a total or partial disconnect between the integrated circuit and the pin package. In these cases it is advantageous and more accurate to compare the output signal at the pin of the pin package with the output signal at the output signal line of the integrated circuit. Implementing the multiplexer (122), high impedance load (218) and amplifier (120) are implemented as part of the integrated circuit (102) in the integrated circuit bypasses testing of the output signal at the pin of the package.

Although in the system of FIG. 1 the multiplexer (122) high impedance load (218) and amplifier (120) are implemented in the integrated circuit (102), the multiplexer (122), high impedance load (218) and amplifier (120) may also be implemented external to the integrated circuit. That is, the multiplexer (122), high impedance load (218) and amplifier (120) may be implemented as an external testing circuit. Such an external testing circuit may be implemented on the same printed circuit board as the integrated circuit, may be integrated on a separate printed circuit board, may be implemented as in a testing probe or in other ways as will occur to those of skill in the art.

The arrangement of signal lines, pins, resistors, and amplifier making up the exemplary system illustrated in FIG. 1 are for explanation, not for limitation. Electrical systems useful according to various embodiments of the present invention may include additional resistors, capacitors, inductors, integrated circuits, pin packages, and electrical circuitry and components, not shown in FIG. 1, as will occur to those of skill in the art. Various embodiments of the present invention may be implemented on a variety of hardware platforms in addition to those illustrated in FIG. 1.

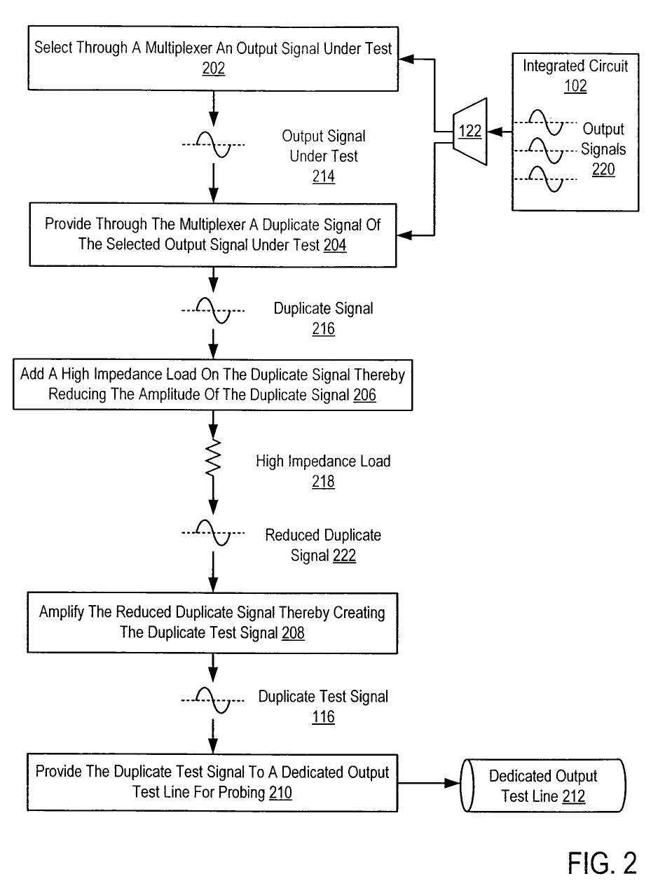

For further explanation, FIG. 2 sets forth a flow chart illustrating an exemplary method for providing a duplicate test signal of an output signal under test in an integrated circuit according to embodiments of the present invention. The method of FIG. 2 includes selecting (202) through a multiplexer (122) an output signal under test (214), the output signal under test (214) selected from a plurality of output signals (220) of the integrated circuit (102). Selecting (202) an output signal under test (214) may be carried out by transmitting, on control signal lines of the multiplexer, one or more control signals corresponding to the input of the multiplexer connected to the output signal line on which is the output signal under test.

The method of FIG. 2 also includes providing (204) through the multiplexer (122) a duplicate signal (216) of the selected output signal under test (214). Providing (204) through the multiplexer (122) a duplicate signal (216) of the selected output signal under test (214) may be carried out by electrically connecting the input associated with the selected output signal under test to the output line of the multiplexer.

The method of FIG. 2 also includes adding (206) a high impedance load (218) on the duplicate signal (216) thereby reducing the amplitude of the duplicate signal (216). Adding (206) a high impedance load (218) on the duplicate signal (216) may be carried out by transmitting the duplicate signal through a resistor or any other high impedance electrical component as will occur to those of skill in the art.

The method of FIG. 2 also includes amplifying (208) the reduced duplicate signal (222) thereby creating the duplicate test signal (116). Amplifying (208) the reduced duplicate signal (222) may be carried out by transmitting the reduced duplicate signal (222) through an operational amplifier having a gain or other amplification circuitry as will occur to those of skill in the art.

The method of FIG. 2 also includes providing (210) the duplicate test signal (116) to a dedicated output test line (212) for probing. Providing (210) the duplicate test signal (116) to a dedicated output test line (212) for probing may be carried out by transmitting the duplicate test signal through an electrical trace on a printed circuit board to a via or through-hole on the printed circuit board. A probe may be inserted into the via or through-hole to test the duplicate test signal or a wire connecting a probe may be soldered onto either the via or the through-hole. As an alternative to providing the duplicate test signal to a dedicated output test line for probing, the duplicate test signal (116) may be provided through a line connected to other electrical components that, for example, monitor the duplicate test signal or transform the signal for running particular tests.

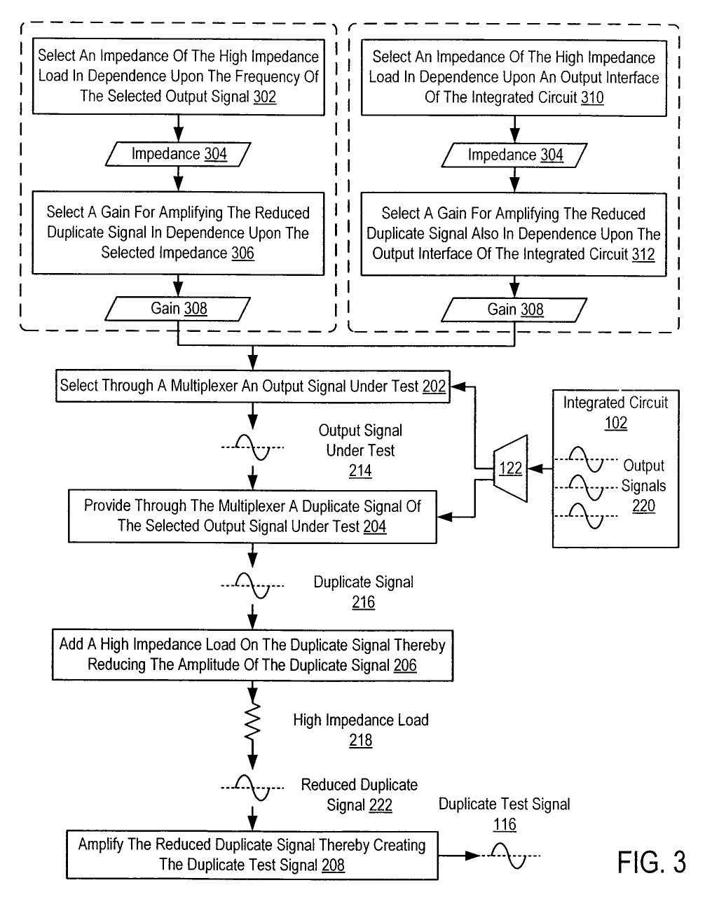

For further explanation, FIG. 3 sets forth a flow chart illustrating a further exemplary method for providing a duplicate test signal of an output signal under test in an integrated circuit according to embodiments of the present invention. The method of FIG. 3 is similar to the method of FIG. 2 in that the method of FIG. 3 includes selecting (202) through a multiplexer (122) an output signal under test (214); providing (204) through the multiplexer (122) a duplicate signal (216) of the selected output signal under test (214); adding (206) a high impedance load (218) on the duplicate signal (216) thereby reducing the amplitude of the duplicate signal (216); and amplifying (208) the reduced duplicate signal (222) thereby creating the duplicate test signal (116).

The method of FIG. 3 differs from the method of FIG. 2, however, in that the method of FIG. 3 includes two methods, enclosed in dashed lines in FIG. 3, for selecting an impedance and a gain that may be carried out independently or dependently such that the selection of an impedance and a gain may be fine tuned. The method of FIG. 3 includes, for example, selecting (302) an impedance (304) of the high impedance load (218) in dependence upon a frequency of the selected output signal under test (214) and selecting (306) a gain for amplifying the reduced duplicate signal (222) in dependence upon the selected impedance (304). Selecting (302) an impedance (304) and selecting (306) a gain (308) may be carried out through trial and error by selecting the highest impedance value that results in a duplicate test signal that is an accurate representation of the output signal under test. The higher the impedance that is selected, the greater is the reduction in amplitude of the reduced duplicate signal. Above a particular impedance value, the amplitude of the reduced duplicate signal is so low that an amplifier cannot create an accurate representation of the output signal under test after amplification. In contrast, the lower the impedance that is selected, the greater the amplitude of the reduced duplicate signal, but the greater the current draw from the output signal under test and the greater the possibility of parasitic effects upon the output signal under test.

The method of FIG. 3 also includes selecting (310) an impedance (304) of the high impedance load (218) in dependence upon an output interface of the integrated circuit (102) and selecting (312) a gain (308) for amplifying the reduced duplicate signal (222) also in dependence upon the output interface of the integrated circuit (102). An output interface is the type of physical interface of an integrated circuit as well as the encoding scheme of data transmitted on output signal lines of the integrated circuit. The output interface of the integrated circuit may be, for example, a double-data-rate two synchronous dynamic random access memory (‘DDR2 SDRAM’) computer memory interface, a Universal Serial Bus (‘USB’) interface, a Peripheral Component Interconnect (‘PCI’) express and so on as will occur to those of skill in the art. Each output interface may be characterized by a different encoding schemes for the data transmitted on the output signal lines of the integrated circuit. Differences in encoding schemes may include voltage levels, current levels, frequency, and so on. Selecting (310) an impedance and selecting (312) a gain in dependence upon the output interface may be carried out by selecting a standard impedance and gain combinations established for a particular output interface. Standard impedance and gain combinations may include, for example, a combination for USB interfaces, PCI express interfaces, DDR2 SDRAM interfaces, and so on as will occur those of skill in the art.

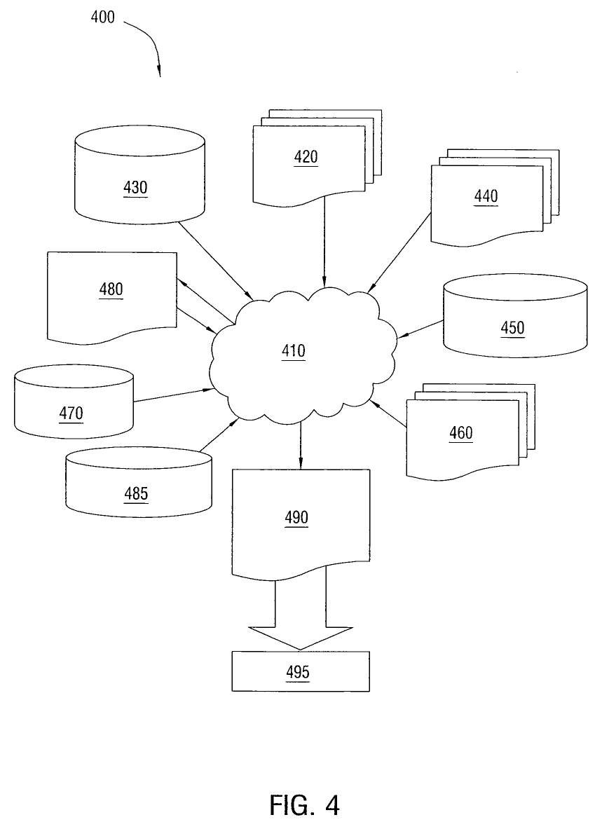

FIG. 4 shows a block diagram of an exemplary design flow (400) used for example, in semiconductor design, manufacturing, and/or test. Design flow (400) may vary depending on the type of IC being designed. For example, a design flow (400) for building an application specific IC (ASIC) may differ from a design flow (400) for designing a standard component. Design structure 420 is preferably an input to a design process (410) and may come from an IP provider, a core developer, or other design company or may be generated by the operator of the design flow, or from other sources. Design structure (420) comprises the circuit described above and shown in FIG. 1 in the form of schematics or HDL, a hardware-description language (e.g., Verilog, VHDL, C, etc.). Design structure (420) may be contained on one or more machine readable medium. For example, design structure (420) may be a text file or a graphical representation of a circuit as described above and shown in FIG. 1. Design process (410) preferably synthesizes (or translates) the circuit described above and shown in FIG. 1 into a netlist (480), where netlist (480) is, for example, a list of wires, transistors, logic gates, control circuits, I/O, models, etc. that describes the connections to other elements and circuits in an integrated circuit design and recorded on at least one of machine readable medium. For example, the medium may be a storage medium such as a CD, a compact flash, other flash memory, or a hard-disk drive. The medium may also be a packet of data to be sent via the Internet, or other networking suitable means. The synthesis may be an iterative process in which netlist (480) is resynthesized one or more times depending on design specifications and parameters for the circuit.

Design process 410 may include using a variety of inputs; for example, inputs from library elements 430 which may house a set of commonly used elements, circuits, and devices, including models, layouts, and symbolic representations, for a given manufacturing technology (e.g., different technology nodes, 32 nm, 45 nm, 90 nm, etc.), design specifications (440), characterization data (450), verification data (460), design rules (470), and test data files (485) (which may include test patterns and other testing information). Design process (410) may further include, for example, standard circuit design processes such as timing analysis, verification, design rule checking, place and route operations, etc. One of ordinary skill in the art of integrated circuit design can appreciate the extent of possible electronic design automation tools and applications used in design process (410) without deviating from the scope and spirit of the invention. The design structure of the invention is not limited to any specific design flow.

Design process (410) preferably translates a circuit as described above and shown in FIG. 1, along with any additional integrated circuit design or data (if applicable), into a second design structure (490). Design structure (490) resides on a storage medium in a data format used for the exchange of layout data of integrated circuits (e.g. information stored in a GDSII (GDS2), GL1, OASIS, or any other suitable format for storing such design structures). Design structure (490) may comprise information such as, for example, test data files, design content files, manufacturing data, layout parameters, wires, levels of metal, vias, shapes, data for routing through the manufacturing line, and any other data required by a semiconductor manufacturer to produce a circuit as described above and shown in FIG. 1. Design structure (490) may then proceed to a stage (495) where, for example, design structure (490): proceeds to tape-out, is released to manufacturing, is released to a mask house, is sent to another design house, is sent back to the customer, etc.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A design structure embodied in a machine readable storage medium for at least one of designing, manufacturing, and testing a design, the design structure comprising:
an integrated circuit for providing a duplicate test signal of an output signal under test, the integrated circuit comprising:
a plurality of output signal lines;
a multiplexer, the multiplexer having as inputs the output signal lines;
a high impedance load, the high impedance load connected to an output of the multiplexer; and
an amplifier; the amplifier connecting the high impedance load to an output test line.

2. The design structure of claim 1 wherein the high impedance load and the amplifier comprise a single component of the integrated circuit.

3. The design structure of claim 1 wherein the output test line is a dedicated signal line on the integrated circuit.

4. The design structure of claim 1 wherein the integrated circuit is a flip chip and output test line is a dedicated signal line on a pin package attached to the integrated circuit.

5. The design structure of claim 1 wherein the integrated circuit is a wire bond integrated circuit and the output test line is a dedicated signal line on the integrated circuit itself.

6. The design structure of claim 1, wherein the design structure comprises a netlist, which describes the integrated circuit.

7. The design structure of claim 1, wherein the design structure resides on the machine readable storage medium as a data format used for the exchange of layout data of integrated circuits.

8. A design structure embodied in a machine readable storage medium for at least one of designing, manufacturing, and testing a design, the design structure comprising:
an apparatus for providing a duplicate test signal of an output signal under test, the apparatus comprising:
an integrated circuit, the integrated circuit comprising a plurality of output signal lines;
a multiplexer, the multiplexer having as inputs the output signal lines;
a high impedance load, the high impedance load connected to an output of the multiplexer; and
an amplifier, the amplifier connecting the high impedance load to an output test line.

9. The design structure of claim 8 wherein the high impedance load and the amplifier comprise a single component.

10. The design structure of claim 8 wherein the integrated circuit is a flip chip.

11. The design structure of claim 8 wherein the integrated circuit is a wire bond integrated circuit.

12. The design structure of claim 8, wherein the design structure comprises a netlist, which describes the apparatus.

13. The design structure of claim 8, wherein the design structure resides on the machine readable storage medium as a data format used for the exchange of layout data of integrated circuits.
